(19) United States
(12) Patent Application Publication
(10) Pub. No.: US 2015/0179410 A1
(43) Pub. Date: Jun. 25, 2015

(54) DRY ETCHING DEVICE AND ELECTRODE THEREOF

(71) Applicants: Chengdu Tianma Micro-Electronics Co., Ltd., Sichuan (CN); Tianma Micro-Electronics Co., Ltd., Shenzhen (CN)

(72) Inventors: Yunlong Ji, Sichuan (CN); Xiaolong Guo, Sichuan (CN); Zitong Hua, Sichuan (CN); Dong Yang, Sichuan (CN)

(73) Assignees: Chengdu Tianma Micro-Electronics Co., Ltd., Sichuan (CN); Tianma Micro-Electronics Co., Ltd., Shenzhen (CN)

(21) Appl. No.: 14/288,182

(22) Filed: May 27, 2014

(30) Foreign Application Priority Data
Dec. 24, 2013 (CN) 201310721996.0

(51) Int. Cl. H01J 37/32

(52) U.S. Cl. CPC H01J 37/32541

(57) ABSTRACT

The invention discloses a dry etching device and an electrode thereof. The electrode comprises an electrode base, an insulation layer arranged on the electrode base, and an edge stage located on a peripheral surface of the insulation layer. The edge stage comprises at least a pad each for receiving a lifter pin of the dry etching device. The edge stage comprises various embosses arranged peripherally on the edge stage, so that small gaps are present around the embosses between the substrate and the edge stage. Therefore, the adhesive force between the substrate and the edge stage can be reduced, the adsorption phenomenon can be efficiently improved, the yield of the etched substrate can be enhanced and the life of the electrode of the dry etching device can be increased.

### CROSS-REFERENCES TO RELATED APPLICATIONS

This application claims the priority of a Chinese patent application No. 201310721996.0 filed on Dec. 24, 2013 and entitled “Dry Etching Device And Electrode Thereof”, the content of which is incorporated herein by reference in its entirety.

### FIELD OF THE INVENTION

The present invention relates to the field of dry etching technique, and more particularly, to a dry etching device and an electrode thereof.

### BACKGROUND OF THE INVENTION

Among photolithography processes, dry etching process has increasingly approached technological maturity. The dry etching process generally uses a plasma discharge to etch off a metal or nonmetal film which is not covered by a photoresist or not shielded by a hard mask such as silicon dioxide (SiO₂) on a substrate, and a region covered by the photoresist or shielded by the hard mask is preserved, so that a desired pattern is formed on the substrate.

The dry etching process is performed on the substrate in a reaction chamber of a dry etching device. FIG. 1 is a schematic view of a reaction chamber of a dry etching device in the prior art. As shown in FIG. 1, the reaction chamber of the dry etching device includes a chamber body 10, an upper electrode 11 positioned on the chamber body 10 and a lower electrode 12 positioned in the chamber body 10. To perform the dry etching on the substrate, the substrate 13 is deposed on the lower electrode 12 which is also referred to as a bottom electrode. FIG. 2 is a schematic sectional view of the lower electrode of the dry etching device in the prior art, and FIG. 3 is a top view of the lower electrode of the dry etching device in the prior art. As shown in FIGS. 2 and 3, the lower electrode of the dry etching device includes an electrode base 210, an insulation layer 220 arranged on the electrode base 210, and an edge stage 230 located peripherally on the insulation layer 220, where the edge stage 230 includes semi-circular shaped pads 231 for mounting lifter pins of the dry etching device, and the lifter pins are mounted in lifter pin holes 232 in the pads 231.

The edge stage 230 of the lower electrode 12 is used to prevent a cooling gas in the lower electrode 12 from overflowing from a top side of the lower electrode 12. However, because the edge stage 230 is slightly higher than a center of the lower electrode 12, an edge area of the substrate is in tight contact with the edge stage 230 when the substrate is laid on the lower electrode 12, thus an adsorption phenomenon happens to the etched substrate when upraising the substrate. As the lower electrode 12 is used again and again, various substances (including silicide and photoresist) from the back of the substrate can be deposited continuously on the edge stage 230, thus the adsorption phenomenon will become more and more serious because the deposited substances are difficult to remove. FIG. 4 is a schematic view of the adsorption phenomenon happens to the etched substrate 13 during the uprising of the etched substrate 13 in the prior art. As shown in FIG. 4, the adsorption phenomenon refers to that the etched substrate 13 is absorbed to the edge stage 230 together during the uprising of the etched substrate 13. The adsorption phenomenon may break the substrate 13, thereby adversely affecting the yield of the substrate.

### BRIEF SUMMARY OF THE INVENTION

An embodiment of the present invention provides an electrode of a dry etching device, including: an electrode base, an insulation layer arranged on the electrode base and an edge stage located peripherally on the insulation layer, the edge stage includes at least a pad each for mounting (or receiving) a lifter pin of the dry etching device, wherein the edge stage includes a plurality of embosses which are arranged peripherally on the edge stage.

An embodiment of the present invention also provides a dry etching device, which includes the electrode of the dry etching device provided by any embodiments of the present invention.

### BRIEF DESCRIPTION OF THE DRAWINGS

FIG. 1 is an illustration of a reaction chamber of a dry etching device in the prior art;

FIG. 2 is a cross-sectional view of a lower electrode of the dry etching device in the prior art;

FIG. 3 is a top view of the lower electrode of the dry etching device in the prior art;

FIG. 4 is an illustration of an adsorption phenomenon happened to the etched substrate during upraising of the etched substrate in the prior art;

FIG. 5 is a top view of an electrode of a dry etching device according to an embodiment of the present invention;

FIG. 6 is a schematic sectional view of an electrode of a dry etching device according to an embodiment of the present invention taken along line A-A′ in FIG. 5;

FIG. 7A is a top view of an electrode of a dry etching device according to an embodiment of the present invention, without a lifter pin in a lifter pin hole;

FIG. 7B is a top view of an electrode of a dry etching device according to an embodiment of the present invention, with a lifter pin in a lifer pin hole;

FIG. 8 is a top view showing at least a pad each having a trapezoidal sectional shape in an electrode of a dry etching device according to an embodiment of the present invention.

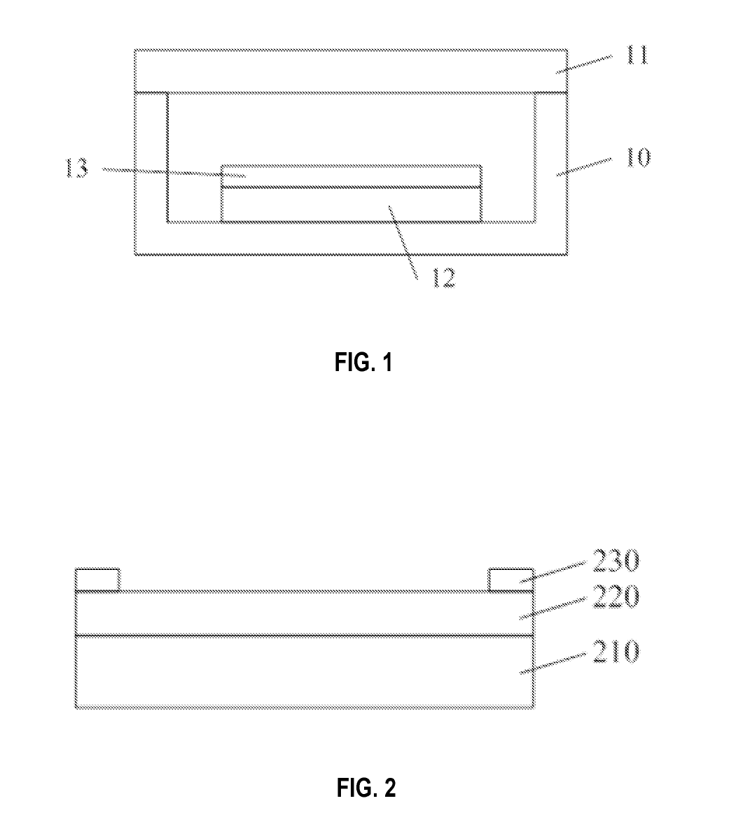

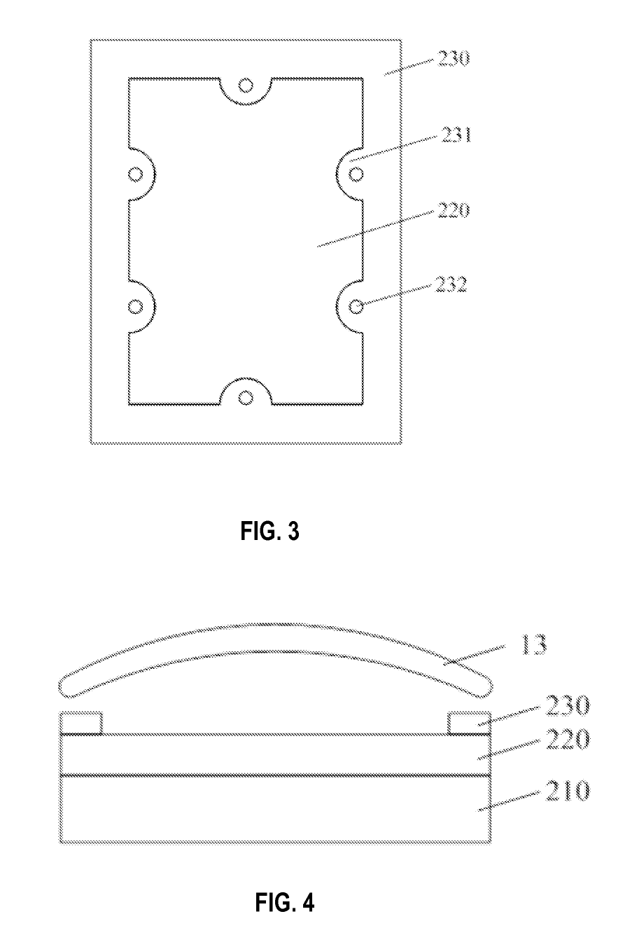

### DETAILED DESCRIPTION OF THE INVENTION

The present invention will be further described in detail with reference to the accompanying drawings and the embodiments. It should be understood that the embodiments described herein are illustrative and not restrictive. In addition, it would be further noted that the accompanying drawings only illustrate partial structures associated with the present invention instead of all structures, for the sake of clarity.

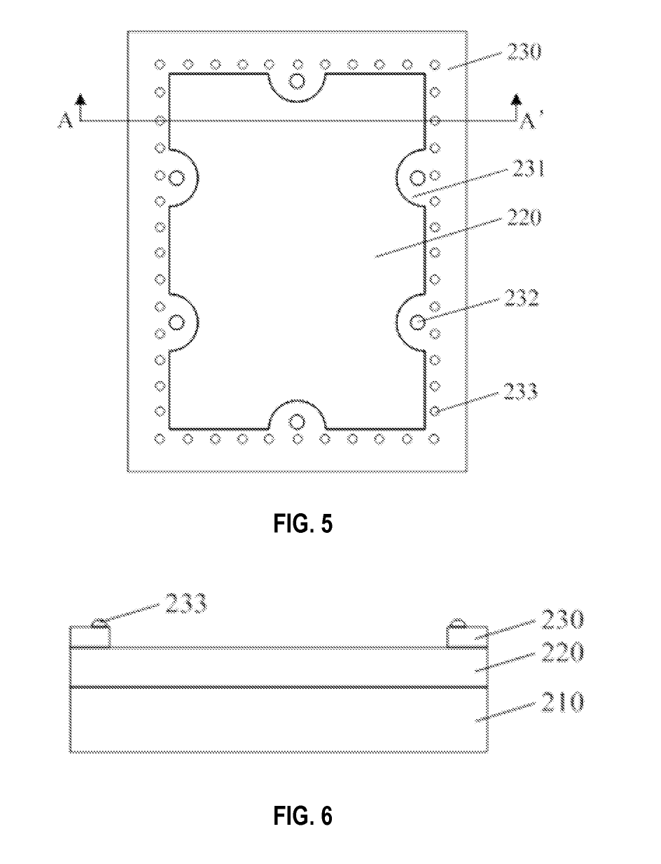

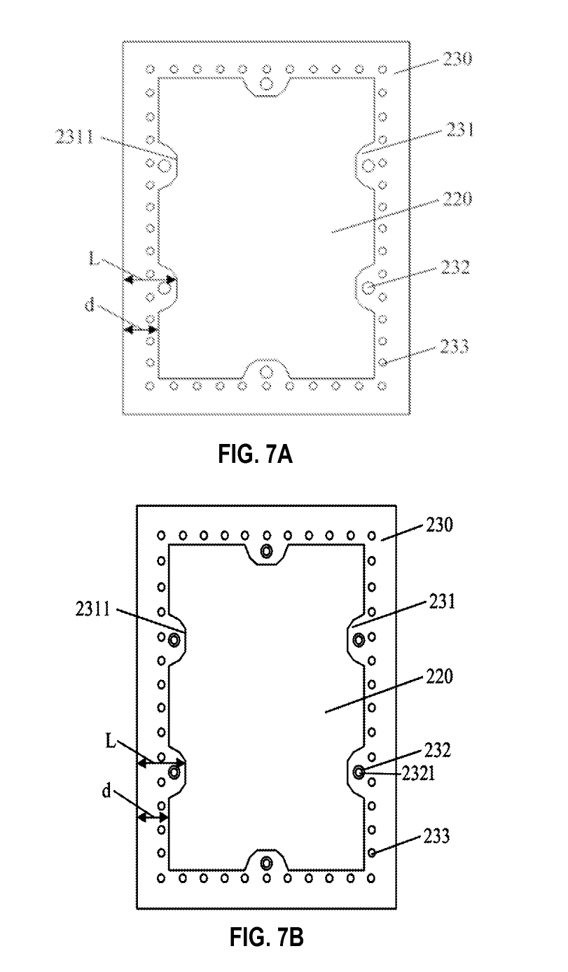

FIG. 5 is a top view of an electrode of a dry etching device according to an embodiment of the present invention. FIG. 6 is a simplified sectional view showing the electrode of a dry etching device taken along the line A-A′ in FIG. 5. The electrode of the dry etching device provided by the embodiment is a lower electrode of a dry etching device, which is also referred to as a bottom electrode. As shown in FIGS. 5 and 6, the electrode of the dry etching device provided by the embodiment includes: an electrode base 210, an insulation layer 220 arranged on the electrode base 210, and an edge stage 230 located on a peripheral surface of the insulation layer 220. The edge stage 230 has at least a pad 231 (which shows for multiple in FIG. 5) each for receiving a lifter pin 2321 (shown in FIG. 7B) of the dry etching device. Each lifter pin 2321 is mounted in a respective lifter pin hole 232. The edge stage 230 also includes a plurality of embosses (i.e., protruding structures) 233, which are arranged peripherally on the edge stage 230. In an embodiment, the insulation layer 220 has a plurality of ventilation holes (not shown) through which a cooling gas passes. Each of the pads 231 is configured to prevent the cooling gas from overflowing from the lifter pin holes 232. It should be appreciated that the shape of the embosses 233 is not limit to those shown in FIGS. 5 and 6. An upper surface (i.e. a side surface which is close to the substrate placed thereon) of each of the plurality of embosses 233 may be flat or curved (convex), and a bottom surface of each of the embosses 233 may have a circular shape, a rectangle shape or other shapes. The shape of the bottom surface of the plurality of embosses 233 is not limited herein.

Due to the presence of embosses arranged peripherally on the edge stage, a small gap between the substrate and the edge stage exists where each emboss is set and the substrate will not be in tight contact with the entire edge stage. In addition, because the height of the embosses is small relative to that of the edge stage, and the substrate (e.g., semiconductor wafer) has a certain flexibility, the edge of the substrate may still have a direct contact with the edge stage, without affecting the function of the edge stage to prevent a gas leakage. Therefore, the adhesive force between the substrate and the edge stage can be significantly reduced, and the adsorption phenomenon can be efficiently improved, thereby significantly enhancing the life of the lower electrode.

In an embodiment, the embosses 233 arranged on a side of the edge stage 230 may be close to a region surrounded by the edge stage 230. For example in this embodiment, the embosses 233 arranged on a side of the edge stage 230 are disposed close to the insulation layer 220 surrounded by the edge stage 230. Due to the flexibility of the substrate, the edge of the substrate may be in contact with the edge stage 230 when the substrate is etched, thus the gas overflow can be prevented. Also, since the substrate can be supported by the embosses 233 arranged on the side of the edge stage 230 which is close to the region surrounded by the edge stage 230, there exists a gap around each of the embosses 233 between the substrate and the edge stage 230, thus the adhesive force between the substrate and the edge stage may be reduced, the adsorption phenomenon may be improved and yield of the etched substrate may be enhanced.

Alternatively, the embosses arranged on a side of the edge stage may be disposed away from the region surrounded by the edge stage, i.e., a side of the edge stage that is disposed away from the insulation layer 220 surrounded by the edge stage. In etching the substrate, due to the flexibility of the substrate, an edge of the substrate may be in contact with a side of the edge stage that is close to the region surrounded by the edge stage, thus the gas overflow can be prevented. Also, since the substrate can be supported by the plurality of embosses arranged on the side of the edge stage that are disposed away from the region surrounded by the edge stage, there exists a gap around each of the embosses 233 between the substrate and the edge stage, which has the same beneficial effects as the case where the plurality of embosses are arranged on the side of the edge stage that are close to the region surrounded by the edge stage.

In an embodiment, the embosses can be evenly arranged on a side of the edge stage, and such even arrangement of the embosses allow for balanced distribution of the adhesive force between the substrate and the edge stage and avoid the case that the etched substrate is applied by forces unevenly in upraising the substrate.

In an embodiment, the embosses and the edge stage can be formed into an integrated body, i.e. formed integrally, to prevent the plurality of embosses from peeling off. In other words, the embosses are formed integrally with formation of the edge stage.

In an embodiment, the embosses, the edge stage and the insulation layer may be made of ceramics which can bear a high working temperature.

In the embodiment, the embosses 233 are arranged peripherally on the edge stage 230 of the electrode of the dry etching device, so that there exists small gaps around the embosses 233 between the edge stage 230 and the substrate placed thereon. Therefore, the adhesive force between the substrate and the edge stage 230 can be reduced, the adsorption phenomenon can be efficiently improved, the yield of the etched substrate can be enhanced and the life of the electrode of the dry etching device can be increased.

FIG. 7A is a top view of an electrode of a dry etching device provided by an embodiment of the present invention, without a lifter pin in a lifter pin hole. FIG. 7B is a top view of an electrode of a dry etching device according to an embodiment of the present invention, with a lifter pin in a lifer pin hole. The electrode of the dry etching device provided by the embodiment is a lower electrode of the dry etching device, which is also referred to as a bottom electrode. Compared with the shape of pads of a dry etching device in the prior art, the shape of the pads of the electrode of the dry etching device provided by the embodiment is improved on the basis of the previous embodiments. As shown in FIG. 7A, the electrode of the dry etching device provided by the embodiment includes an electrode base (not shown in FIG. 7A), an insulation layer 220 arranged on the electrode base, and an edge stage 230 located peripherally on the insulation layer 220 (for example, arranged on the perimeter of the insulation layer 220). The edge stage 230 has at least a pad 231 (which shows for multiple in FIG. 7A) each configured to receive a lifter pin 2321 (shown in FIG. 7B) of the dry etching device, and the lifter pin 2321 is mounted in a lifter pin hole 232 in pad 231. It is understood that the number of pads can be any integer number. In the example shown in FIG. 7A, six pads are used, but it is understood that the number is arbitrary chosen for describing the example embodiment and not be limiting. The edge stage 230 includes a plurality of embosses 233, which are arranged peripherally on the edge stage 230. Pad 231 has a polygonal shape which includes at least one side 2311 protruding toward the region surrounded by the edge stage 230. It can be understood that pad 231 includes at least one side 2311 protruding toward the surrounded insulation layer 220 in the present embodiment. In an embodiment, the pad may have a triangular shape or other shapes which protrudes toward the surrounded insulation layer. In the case that the pad has the triangular shape, two sides (i.e. two adjacent sides forming a protruding angle of the triangular shape) of the pad protrude toward the surrounded insulation layer.

In a semi-circular shaped pad of the electrode of the dry etching device in the prior art, the point along the profile of the pad which most protrudes towards the region surrounded by the edge stage is very distant from an outer peripheral edge of the edge stage, for example, by a distance of 12.5 mm in the existing dry etching device in the prior art. Thus, a contact area between the substrate and the pad of the edge stage is large, which negatively affects a number of substrates (i.e. a quantity of laid out substrates) which can be subjected to a dry etching process simultaneously. In addition, due to reasons such as temperature and an electric field, the etching speed will be increased in the contact region between the substrate and the pad of the edge stage, which results in partially uneven etching as well as Electro-Static Discharge (EDS) which may further result in a damage of the substrate (e.g. wirings in the substrate). The pad 231 of the electrode of the dry etching device according to an embodiment of the present invention is improved by having a polygonal structure. The improved structure of the invention has numerous advantages and benefits in that: the function of preventing gas overflow is retained, but the distance between a point along the at least one side of the pad which most protrudes towards the region (such as the surrounded insulation layer 220 in the example) surrounded by the edge stage and the outer peripheral edge of the edge stage can be reduced, so that the area of the pad can be reduced, the contact area between the substrate and the pad of the edge stage can be reduced, the substrate can be etched evenly, the risk of ESD occurring at the contact region between the substrate and the pad of the edge stage can be reduced, and a guaranteed etched area and the quantity of laid out substrates can be enhanced.

In an embodiment, as shown in FIG. 7A, the distance L between the point along the at least one side 2311 of the pad which most protrudes towards the region surrounded by the edge stage and the outer peripheral edge of the edge stage is 4/3 to 3/2 times of a width d of the edge stage, thus the guaranteed etched area can be increased and the quantity of the laid out substrates can be enhanced, while retaining the function of the pad to prevent the gas overflow.

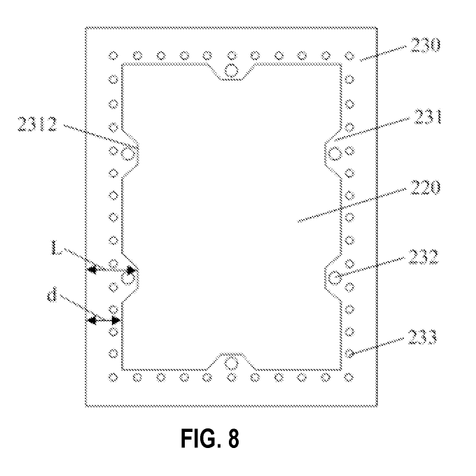

In an implementation of the embodiment, the pad 231 may have a trapezoidal shape. FIG. 8 is a top view showing at least a pad each having a trapezoidal shape in an electrode of a dry etching device provided by an embodiment of the present invention. As shown in FIG. 8, a short side 2312 of the trapezoidal shape protrudes toward the region surrounded by the edge stage, to further reduce the area of the pad. In the prior art, the edge stage is relatively wide, for example, a width of the edge stage in the existing dry etching device is 8 mm, thus a contact area between the substrate and the edge stage is big, thereby affecting a guaranteed etched area and a quantity of the laid out substrates. Further, due to reasons such as temperature and the electric field, an etching speed will be increased in the contact region between the substrate and the edge stage, which results in partially uneven etching as well as ESD. Therefore, in an embodiment, the width d of the edge stage can be 6 mm, and the distance L between the short side 2312 of the pad and the outer peripheral edge of the edge stage can be 8 mm, thus the contact area between the substrate and the edge stage is reduced, even etching for the substrate can be ensured, the risk of ESD occurring in the contact region can be reduced, and the guaranteed etched area and the quantity of the laid out substrates can be further enhanced.

Based on the electrode of the dry etching device provided by the previous embodiments, the electrode of the dry etching device provided by the present embodiment includes the pad of an improved shape which is polygonal, thereby obtaining the following advantages in that: the distance between a point along the at least one side of the pad which most protrudes toward the region surrounded by the edge stage and the outer peripheral edge of the edge stage can be reduced, the area of the pad can be reduced as well as the guaranteed etched area and the quantity of the laid out substrates can be increased.

An embodiment of the present invention provides a dry etching device, which includes the electrode provided by any previous embodiments of the present invention. Specifically, the dry etching device can include a chamber body, an upper electrode positioned on the chamber body, and a lower electrode positioned inside the chamber body, where the electrode provided by any previous embodiments of the present invention may be used as the lower electrode of the dry etching device provided by the present embodiment.

The dry etching device provided by the present embodiment has the beneficial effects achieved by the electrode of a dry etching device provided by a corresponding embodiment of the present, that is, reducing the adhesive force between the substrate and the edge stage, efficiently improving the adsorption phenomenon, enhancing the yield of the etched substrates and increasing the life of the electrode of the dry etching device.

It is noted that the above description illustrates the preferred embodiments and the applied technical principle of the present invention. It is to be understood, however, that even though advantages of the present invention have been set forth in the foregoing description, the disclosure is illustrative only, and changes may be made in matters of shape, size, and arrangement of parts within the principles of the invention. Therefore, although the present invention has been described in detail in accordance with the embodiments, the present invention is not limited to the embodiments and can include other equivalent embodiments without departing from the concept of the present invention. The scope of the present invention is defined by the appended claims.

What is claimed is:

1. An electrode of a dry etching device, comprising:
an electrode base;
an insulation layer arranged on the electrode base; and
an edge stage located on a peripheral surface of the insulation layer,
wherein the edge stage comprises at least a pad for receiving a lifter pin of the dry etching device, and
wherein the edge stage comprises a plurality of embosses arranged on a periphery of the edge stage.

2. The electrode of claim 1, wherein the embosses are disposed close to a region surrounded by the edge stage.

3. The electrode of claim 1, wherein the embosses are disposed away from a region surrounded by the edge stage.

4. The electrode of any one of claim 1, wherein the embosses are evenly arranged on the edge stage.

5. The electrode of any one of claim 1, wherein each of the at least a pad has a polygonal shape having at least one side protruding toward a region surrounded by the edge stage.

6. The electrode of claim 5, wherein a distance between a point along the at least one side of the at least a pad that most protrudes toward the region surrounded by the edge stage and an outer peripheral edge of the edge stage is 4/3 to 3/2 times of a width of the edge stage.

7. The electrode of claim 6, wherein the at lease a pad has a trapezoidal shape which has a short side protruding toward the region surrounded by the edge stage.

8. The electrode of claim 7, wherein the width of the edge stage is about 6 mm, and the distance between the short side of the trapezoidal shape of the at least a pad and the outer peripheral edge of the edge stage is about 8 mm.

9. The electrode of claim 1, wherein the embosses and the edge stage are formed integrally.

10. The electrode of claim 9, wherein the embosses each comprise a flat top surface.

11. The electrode of claim 9, wherein the embosses each comprise a curved top surface.

12. The electrode of claim 1, wherein the embosses, the edge stage and the insulation layer are made of ceramics.

13. The electrode of claim 1, wherein the insulation layer comprises a plurality of ventilation holes configured to pass through a cooling gas.

14. A dry etching device comprising an electrode, wherein the electrode comprises:
an electrode base;
an insulation layer arranged on the electrode base; and
an edge stage located peripherally on the insulation layer,
wherein the edge stage comprises at least a pad each for receiving a lifter pin of the dry etching device, and
wherein the edge stage comprises a plurality of embosses arranged on a periphery of the edge stage.
